(19) United States
(12) Patent Application Publication
(10) Pub. No.: US 2023/0369266 A1
(43) Pub. Date: Nov. 16, 2023

(54) WAFER-LEVEL CHIP SCALE PACKAGING WITH COPPER CORE BALL EMBEDDED INTO MOLD

(71) Applicant: Micron Technology, Inc., Boise, ID (US)

(72) Inventor: Jong Sik Paek, Taichung (TW)

(21) Appl. No.: 17/741,200

(22) Filed: May 10, 2022

(51) Int. Cl. H01L 23/00

(52) U.S. Cl. CPC H01L 24/13; H01L 24/03; H01L 24/05; H01L 24/11; H01L 2224/0401; H01L 2224/05024; H01L 2224/12105; H01L 2224/13026; H01L 2224/13147

(57) ABSTRACT

A semiconductor device assembly is provided, including a substrate having a top side and a bottom side opposite the top side; a contact pad formed at the top side of the substrate; an under bump metallization (UBM) structure disposed laterally offset from the contact pad; a redistribution layer electrically coupling the contact pad and the UBM structure; a copper ball electrically coupled to the UBM structure by a solder material; and a molding compound disposed over the redistribution structure and at least partially surrounding the copper ball.

### TECHNICAL FIELD

The present disclosure relates to semiconductor device packaging, and more particularly relates to wafer-level chip scale packaging with copper core ball embedded into molding compound.

### BACKGROUND

The conventional method of packaging semiconductor devices involves dicing a wafer into individual semiconductor devices and attaching the singulated semiconductor devices to a package substrate (e.g., a printed circuit board (PCB)). Maintaining a reliable and resilient solder connection between the semiconductor device and the package substrate can be challenging, however. For example, when a solder connection is provided between an under-bump metallization (UBM) structure of the semiconductor device and the package substrate, reflow heating procedures that are performed to establish physical and electrical contact between the solder and UBM structure can lead to gap (void) formation and/or cracking at the interface between the solder and the UBM structure (as well as at the neck of the solder near the edges of the UBM structure.

### BRIEF DESCRIPTION OF THE DRAWINGS

FIG. 1A is a simplified schematic cross-sectional view of an exemplary semiconductor device assembly in accordance with an embodiment of the present disclosure.

FIG. 1B is a simplified schematic cross-sectional view of the exemplary semiconductor device assembly of FIG. 1A further including a copper ball connection structure in accordance with an embodiment of the present disclosure.

FIG. 1C is a simplified schematic cross-sectional view of the exemplary semiconductor device assembly of FIG. 1B after molding compound deposition in accordance with an embodiment of the present disclosure.

FIG. 1D is a simplified schematic cross-sectional view of the exemplary semiconductor device assembly of FIG. 1C being mounted on an exemplary package substrate in accordance with an embodiment of the present disclosure.

FIG. 2A is a simplified schematic cross-sectional view of an exemplary semiconductor device assembly in accordance with an embodiment of the present disclosure.

FIG. 2B is a simplified schematic cross-sectional view of the exemplary semiconductor device assembly of FIG. 2A further including a copper ball connection structure in accordance with an embodiment of the present disclosure.

FIG. 2C is a simplified schematic cross-sectional view of the exemplary semiconductor device assembly of FIG. 2B after molding compound deposition in accordance with an embodiment of the present disclosure.

FIG. 2D is a simplified schematic cross-sectional view of the exemplary semiconductor device assembly of FIG. 2C being mounted on an exemplary package substrate in accordance with an embodiment of the present disclosure.

FIG. 3A is a simplified schematic cross-sectional view of an exemplary semiconductor device assembly in accordance with an embodiment of the present disclosure.

FIG. 3B is a simplified schematic cross-sectional view of the exemplary semiconductor device assembly of FIG. 3A after a solder ball attach procedure in accordance with an embodiment of the present disclosure.

FIG. 4 is a schematic view showing an exemplary system that includes a semiconductor device assembly configured in accordance with an embodiment of the present disclosure.

FIG. 5 is a flow chart illustrating an exemplary method of making a semiconductor device assembly in accordance with an embodiment of the present disclosure.

While the disclosure is susceptible to various modifications and alternative forms, specific embodiments have been shown by way of example in the drawings and will be described in detail herein. However, it should be understood that the disclosure is not intended to be limited to the particular forms disclosed. Rather, the intention is to cover all modifications, equivalents and alternatives falling within the scope of the disclosure as defined by the appended claims.

### DETAILED DESCRIPTION

Specific details of several embodiments of semiconductor devices, and associated systems and methods, are described below. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

In this disclosure, numerous specific details are discussed to provide a thorough and enabling description for embodiments of the present disclosure. One of ordinary skill in the art will recognize that the disclosure can be practiced without one or more of the specific details. Well-known structures and/or operations often associated with semiconductor devices may not be shown and/or may not be described in detail to avoid obscuring other aspects of the disclosure. In general, it should be understood that various other devices, systems, and/or methods in addition to those specific embodiments disclosed herein may be within the scope of the present disclosure.

The term “semiconductor device assembly” can refer to an assembly of one or more semiconductor devices, semiconductor device packages, and/or substrates, which may include interposers, supports, and/or other suitable substrates. The semiconductor device assembly may be manufactured as, but not limited to, discrete package form, strip or matrix form, and/or wafer panel form. The term “semiconductor device” generally refers to a solid-state device that includes semiconductor material. A semiconductor device can include, for example, a semiconductor substrate, wafer, panel, or a single die from a wafer or substrate. A semiconductor device may further include one or more device layers deposited on a substrate. A semiconductor device may refer herein to a singulated semiconductor die, or to a semiconductor device not yet singulated from a wafer of such devices.

The term “semiconductor device package” can refer to an arrangement with one or more semiconductor devices incorporated into a common package. A semiconductor package can include a housing or casing that partially or completely encapsulates at least one semiconductor device. A semiconductor package can also include a substrate that carries one or more semiconductor devices. The substrate may be attached to or otherwise incorporate within the housing or casing.

The term “substrate” as described in the present disclosure can refer to a package substrate or printed circuit board (PCB). The terms “solder,” “solder ball,” “solder material,” and “solder connection” are used interchangeably in the present disclosure and can refer to any interconnection structure formed on a metal surface, contact, pad or layer of a semiconductor device, semiconductor chip package, package substrate, printed circuit board (PCB), or between a semiconductor device and package substrate or PCB.

As set forth above, when a solder connection is provided between an under-bump metallization (UBM) structure of the semiconductor device and the package substrate, reflow heating procedures that are performed to establish physical and electrical contact between the solder and UBM structure can lead to gap (void) formation and/or cracking at the interface between the solder and the UBM structure (as well as at the neck of the solder near the edges of the UBM structure.

Embodiments of the present disclosure can address these problems and others by, for example, embedding a copper ball in a solder material deposited on a UBM structure laterally offset from a pad of the semiconductor device by a redistribution layer, thereby moving and increasing a possible failure path from a path extending through the solder ball to a path along an exterior surface of the embedded copper ball (e.g., along the arc length between the solder ball and embedded copper core ball). Moreover, by providing a molding compound (e.g., epoxy molding compound (EMC)) to at least surround a lower hemisphere of the copper ball, the location of possible thermal and mechanical stresses can be moved from along the neck of the solder ball at the edges of the UBM layer towards the surface of the molding compound, with a concomitant increase in solder joint reliability (SJR). The EMC, laterally-offsetting redistribution structure, and solder/copper ball structure can help to absorb thermal and mechanical stresses from the package substrate, thereby significantly reducing chip package interaction (CPI) stress on the semiconductor device.

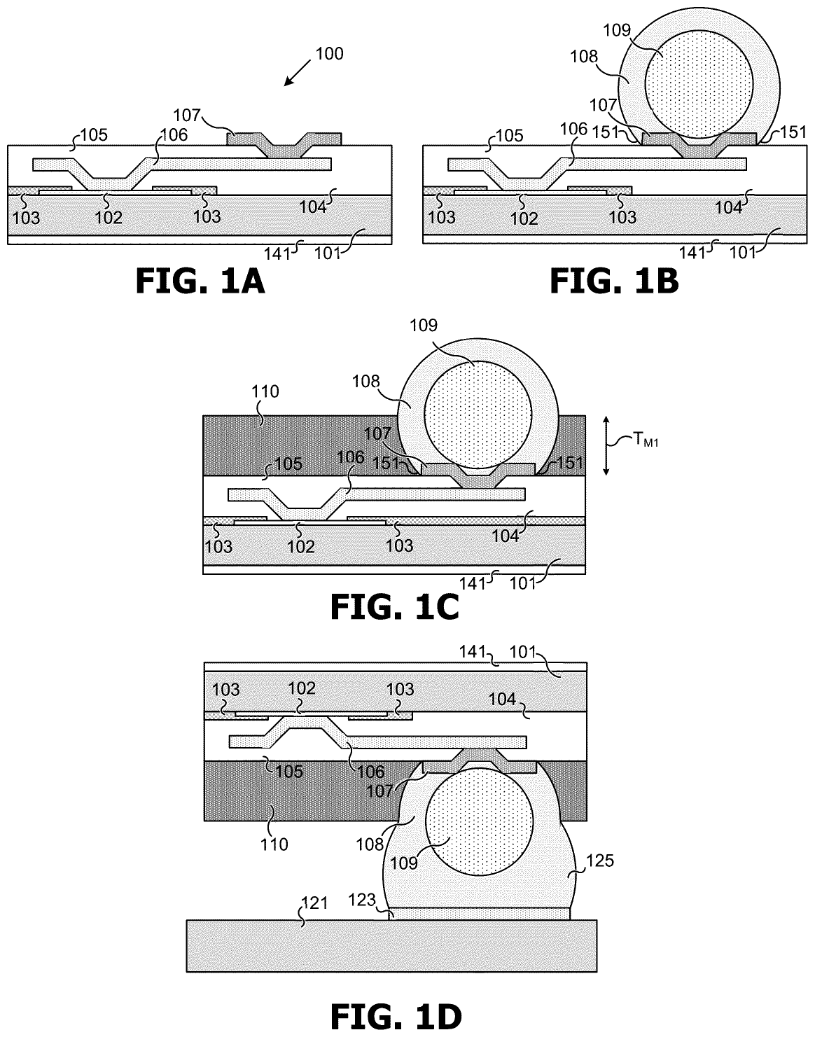

FIG. 1A is a simplified schematic cross-sectional view of an exemplary semiconductor device assembly 100 in accordance with an embodiment of the present disclosure. As can be seen with reference to FIG. 1A, the semiconductor device assembly 100 includes semiconductor device 101 on which are formed contact pad 102, die passivation layers 103, a redistribution layer including passivation layers 104 and 105, and a redistribution structure 106, an under-bump metallization (UBM) structure 107, and optionally a backside passivation layer 141.

As shown in FIG. 1A, the die passivation layer 103 may be formed on a surface of semiconductor device 101 and may partially cover an upper surface of contact pad 102, which connects to integrated circuit structures (not shown) within semiconductor device 101. A redistribution structure 106 (fabricated in one or more metallization steps) in a redistribution layer comprising passivation layers 104 and 105 connects contact pad 102 to UBM structure 107. The redistribution structure 106 permits UBM structure 107 to be laterally offset from the contact pad 102 by a significant distance (e.g., sufficient to prevent any vertical overlap between the UBM structure 107 and the contact pad 102), which can provide a lever arm of sufficient length to absorb some of the stresses caused by connecting the semiconductor device 100 to a package substrate (shown in greater detail below).

FIG. 1B is a simplified schematic cross-sectional view of the exemplary semiconductor device assembly 100 of FIG. 1A further including a solder-covered copper ball physically and electrically connected to the UBM structure 107 in accordance with an embodiment of the present disclosure. As can be seen with reference to FIG. 1B, the solder-covered copper ball includes a generally spherical copper ball 109 surrounded by a layer of solder material 108 and coupled to UBM structure 107 by the solder material 108. Following a reflow operation, the exposed surfaces of the UBM structure 107 are at least partially (e.g., the upper surface) and possibly fully (e.g., the upper surface and exposed sidewalls) encapsulated by the solder material 108.

FIG. 1C is a simplified schematic cross-sectional view of the exemplary semiconductor device assembly of FIG. 1B after molding compound deposition in accordance with an embodiment of the present disclosure. As can be seen with reference to FIG. 1C, a molding compound 110, for example, epoxy mold compound (EMC), has been formed on the semiconductor device 101 and over the redistribution layer (e.g., over the upper passivation layer 105) and completely encapsulating the UBM structure 107 (e.g., to the extent the sidewalls thereof are not already encapsulated by the solder material 108), the passivation layer 105, and at least a lower generally hemispherical portion of the solder-covered copper ball 109. According to one aspect of the present disclosure, the thickness T_{M1} of the molding compound 110 may be equal to or greater than the radius of the copper ball 109.

The molding compound 110 can absorb thermal and mechanical stresses, thereby lowering the CPI stress and reducing stresses on weak points (e.g., voids or fractures) along the neck 151 of the solder material 108. In this regard, the presence of the molding compound 110 can relocate stresses from weak points along the neck 151 of solder material 108 to the surface of the molding compound 110.

FIG. 1D is a simplified schematic cross-sectional view of the exemplary semiconductor device assembly of FIG. 1C after being mounted on an exemplary package substrate in accordance with an embodiment of the present disclosure. As can be seen with reference to FIG. 1D, a solder material 125 is used to couple a contact pad 123 of the package substrate 121 and the solder-covered copper ball 109. The process can involve reflowing both solder material 125 and solder material 108 to form a reliable solder interconnect encapsulating the copper ball 109.

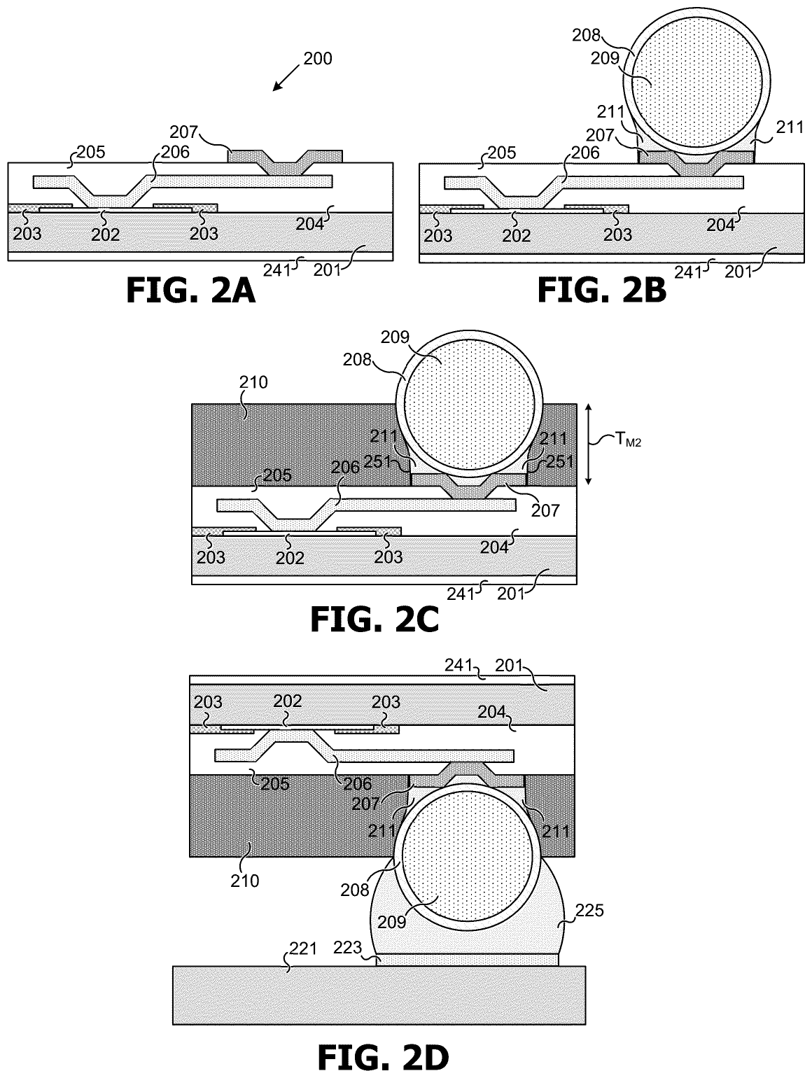

While in the foregoing example embodiments semiconductor devices have been described and illustrated as including interconnects comprising solder-covered copper balls, in other embodiments a copper ball need not be entirely covered with solder to provide similar advantages when used to connect a UBM structure to a package substrate. For example, FIG. 2A is a simplified schematic cross-sectional view of an exemplary semiconductor device assembly 200 in accordance with one such embodiment of the present disclosure. As can be seen with reference to FIG. 2A, the semiconductor device assembly 200 includes semiconductor device 201 on which are formed contact pad 202, die passivation layers 203, a redistribution layer including passivation layers 204 and 205, and a redistribution structure 206, an under-bump metallization (UBM) structure 207, and optionally a backside passivation layer 241.

As shown in FIG. 2A, the die passivation layer 203 may be formed on a surface of semiconductor device 201 and may partially cover an upper surface of contact pad 202, which connects to integrated circuit structures (not shown) within semiconductor device 201. A redistribution structure 206 (fabricated in one or more metallization steps) in a redistribution layer comprising passivation layers 204 and 205 connects contact pad 202 to UBM structure 207. The redistribution structure 206 permits UBM structure 207 to be laterally offset from the contact pad 202 by a significant distance (e.g., sufficient to prevent any vertical overlap between the UBM structure 207 and the contact pad 202), which can provide a lever arm of sufficient length to absorb some of the stresses caused by connecting the semiconductor device 200 to a package substrate (shown in greater detail below).

FIG. 2B is a simplified schematic cross-sectional view of the exemplary semiconductor device assembly 200 of FIG. 2A further including a copper ball physically and electrically connected to the UBM structure 207 in accordance with an embodiment of the present disclosure. As can be seen with reference to FIG. 2B, the copper ball 209 (optionally covered by an anti-oxidation layer 208) can be coupled to UBM structure 207 by a portion of solder material 211 (e.g., provided in a solder screen or solder ball drop operation). Following a reflow operation, the exposed surfaces of the UBM structure 207 are at least partially (e.g., the upper surface) and possibly fully (e.g., the upper surface and exposed sidewalls) encapsulated by the solder material 211, which does not, however, completely encapsulate or surround the copper ball 209.

Examples of material which could be used in the formation of the anti-oxidation layer 208 may be selected from one of carbides, nitrides, polymers, resins, epoxy, polymers, polyimide, polybenzoxazole, benzocyclobuten, plating as well as alloy additives (Al, Ni, Zn) or metals Sn, Ag, Ni, Bi, Au, Ta, Nd, Mo, Nb, Rh, alkali metals, alkali earths, transition metals, or any combination thereof may be used as desired. Any convenient deposition method may be used, including spin coating, chemical vapor deposition (CVD), atomic layer deposition (ALD), vapor deposition polymerization (VDP), physical vapor deposition (PVD), or Electrophoretic deposition (EPD).

FIG. 2C is a simplified schematic cross-sectional view of the exemplary semiconductor device assembly of FIG. 2B after molding compound deposition in accordance with an embodiment of the present disclosure. As can be seen with reference to FIG. 2C, a molding compound 210, for example, epoxy mold compound (EMC), has been formed on the semiconductor device 201 and over the redistribution layer (e.g., over the upper passivation layer 205) and completely encapsulating the UBM structure 207 (e.g., to the extent the sidewalls thereof are not already encapsulated by the solder material 211), the passivation layer 205, and at least a lower generally hemispherical portion of the solder-covered copper ball 209. According to one aspect of the present disclosure, the thickness T_{M1} of the molding compound 210 may be equal to or greater than the radius of the copper ball 209.

The molding compound 210 can absorb thermal and mechanical stresses, thereby lowering the CPI stress and reducing stresses on weak points (e.g., voids or fractures) along the neck 251 of the solder material 208. In this regard, the presence of the molding compound 210 can relocate stresses from weak points along the neck 251 of solder material 208 to the surface of the molding compound 210.

FIG. 2D is a simplified schematic cross-sectional view of the exemplary semiconductor device assembly of FIG. 2C after being mounted on an exemplary package substrate in accordance with an embodiment of the present disclosure. As can be seen with reference to FIG. 2D, a solder material 225 is used to couple a contact pad 223 of the package substrate 221 and the solder-covered copper ball 209. The process can involve reflowing the solder material 225 to form a reliable solder interconnect at least partially encapsulating the protruding portion of copper ball 209 (e.g., the generally hemispherical upper portion protruding above the upper surface of the molding compound 210).

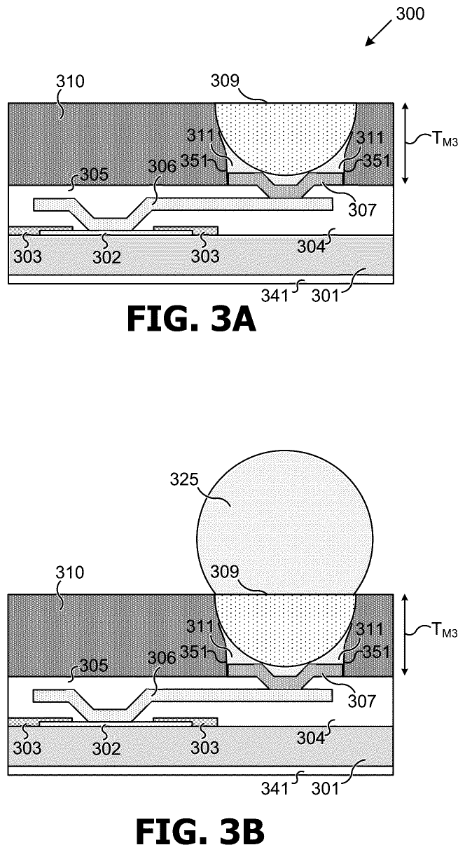

FIG. 3A is a simplified schematic cross-sectional view of an exemplary semiconductor device assembly 300 in accordance with an embodiment of the present disclosure. As can be seen with reference to FIG. 3A, the semiconductor device assembly 300 includes semiconductor device 301 on which are formed contact pad 302, die passivation layers 303, a redistribution layer including passivation layers 304 and 305, and a redistribution structure 306, an under-bump metallization (UBM) structure 307, and optionally a backside passivation layer 341. The redistribution structure 306 permits UBM structure 307 to be laterally offset from the contact pad 302 by a significant distance (e.g., sufficient to prevent any vertical overlap between the UBM structure 307 and the contact pad 302), which can provide a lever arm of sufficient length to absorb some of the stresses caused by connecting the semiconductor device 300 to a package substrate (shown in greater detail below). Semiconductor device assembly 300 further includes a copper interconnect structure physically and electrically connected to the UBM structure 307 in accordance with an embodiment of the present disclosure.

As can be seen with reference to FIG. 3A, the generally hemispherical copper interconnect structure 309 can be coupled to UBM structure 307 by a portion of solder material 311. Semiconductor device assembly 300 further includes a molding compound 310, for example, epoxy mold compound (EMC), formed on the semiconductor device 301 and over the redistribution layer (e.g., over the upper passivation layer 305) and completely encapsulating the UBM structure 307 (e.g., to the extent the sidewalls thereof are not already encapsulated by the solder material 311), the passivation layer 305, and at least a lower generally hemispherical portion of the interconnect structure 309. According to one aspect of the present disclosure, the thickness T_{M3} of the molding compound 310 may be equal to a height of the interconnect structure 309. For example, by planarizing (e.g., with a chemical-mechanical polishing (CMP) process) a semiconductor device like those illustrated in FIGS. 1C and 2C (in which a copper ball protrudes partially from a layer of molding compound 310), a planar surface of the inner copper structure of a solder-covered or solder-attached copper ball can be exposed and made coplanar with an upper surface of the molding compound 310, to server as a pad to which another electrical structure can be attached. For example, a solder ball 325 can be wetted to the exposed planar surface of the interconnect structure 309, as illustrated in FIG. 3B, and used to facilitate the physical and electrical coupling of the semiconductor device assembly 300 to another structure (e.g., a package substrate, another device assembly, etc.).

Although in the foregoing example embodiments, semiconductor device assemblies have been illustrated and described with solder-covered or solder-attached copper balls connected to a redistribution layer by an intervening UBM structure, in other embodiments of the present disclosure similar copper balls can be directly attached to a metal structure of a redistribution layer through an opening in the dielectric thereof, absent any UBM structure, mutatis mutandis.

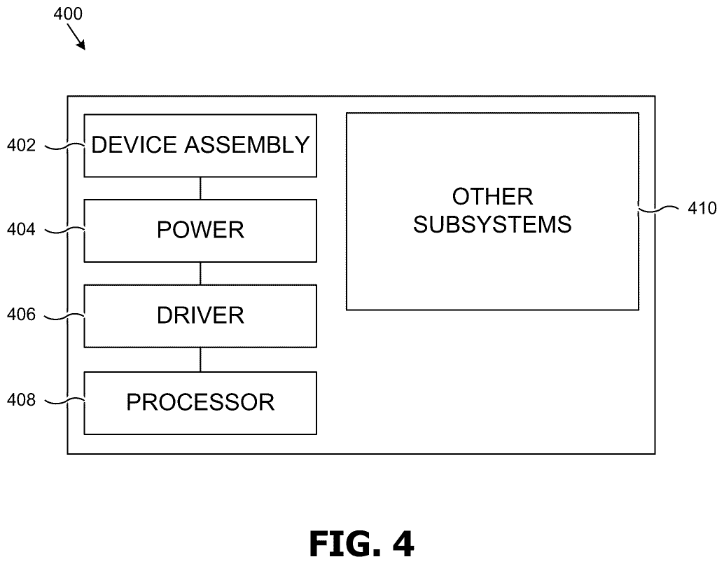

FIG. 4 is a schematic view showing an exemplary system that includes a semiconductor device assembly configured in accordance with an embodiment of the present disclosure. Any one of the exemplary semiconductor devices and semiconductor device assemblies described above with reference to FIGS. 1A-1D, 2A-2D, and 3A-3B may be incorporated into any of a myriad of larger and/or more complex systems, a representative example of which is system 400 shown schematically in FIG. 4. The system 400 may include semiconductor device assembly (e.g., or a discrete semiconductor device) 402, power source 404, driver 406, processor 408, and/or other subsystems or components 410. The semiconductor device assembly 402 may include features generally similar to those of the semiconductor devices described above with reference to FIGS. 1A-1D, 2A-2D, and 3A-3B. The resulting system 400 may perform any of a wide variety of functions, such as memory storage, data processing, and/or other suitable functions. Accordingly, representative systems 400 may include, without limitation, hand-held devices (e.g., mobile phones, tablets, digital readers, and digital audio players), computers, vehicles, appliances and other products. Components of the system 400 may be housed in a single unit or distributed over multiple, interconnected units (e.g., through a communications network). The components of the system 400 may also include remote devices and any of a wide variety of computer readable media.

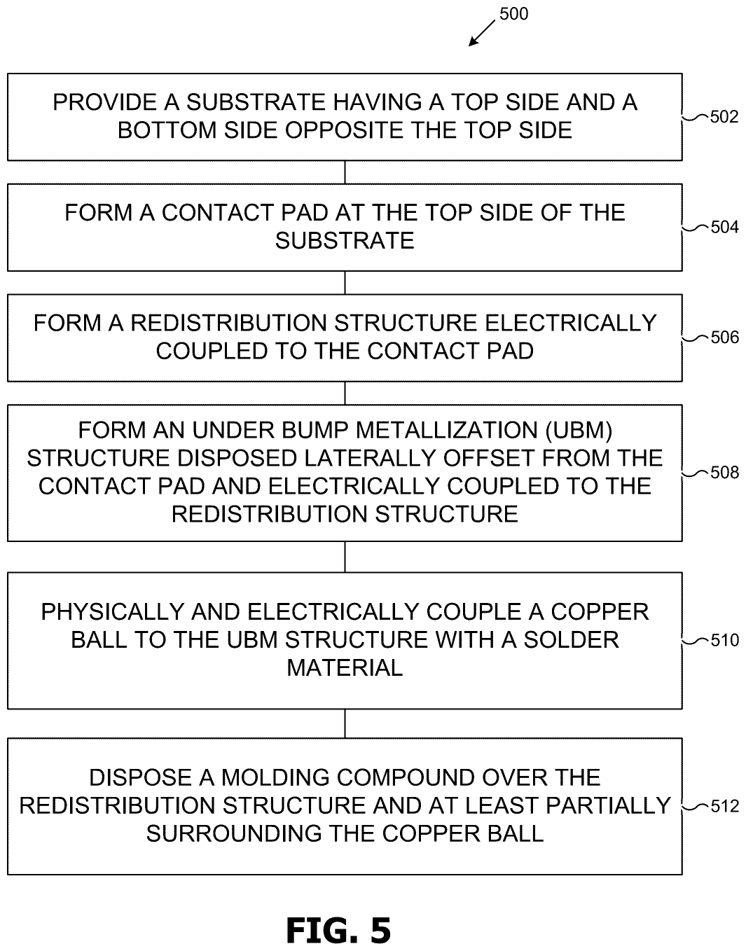

FIG. 5 is a flow chart illustrating an exemplary method of making a semiconductor device assembly in accordance with one aspect of the present disclosure. The method 500 includes providing a substrate having a top side and a bottom side opposite the top side (box 502), forming a contact pad at the top side of the substrate (box 504), forming a redistribution structure electrically coupled to the contact pad (box 506), and forming an under bump metallization (UBM) structure disposed laterally offset from the contact pad and electrically coupled to the redistribution structure (box 508). The method 500 further includes physically and electrically coupling a copper ball to the UBM structure with a solder material (box 510) and disposing a molding compound over the redistribution structure and at least partially surrounding the copper ball (box 512). In some embodiments, the method may further include planarizing the copper ball to form a substantially hemispherical copper structure with an upper surface coplanar with an upper surface of the molding compound, and/or may further include electrically and physically coupling a solder ball to the upper surface of the substantially hemispherical copper structure.

The exemplary method is provided by way of example, as there are a variety of ways to carry out the method. Each box of method 500 may represent one or more processes, methods, or subroutines that are carried out in the exemplary method. Further for explanatory purposes, the boxes of the example method 500 are described herein as occurring in serial, or linearly. However, multiple boxes of the example method 500 may occur in parallel. In addition, the boxes of the example process 500 may be performed a different order than the order shown and/or one or more of the boxes of the example process 500 may not be performed.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” may refer to relative directions or positions of features in the semiconductor devices in view of the orientation shown in the Figures. For example, “upper” or “uppermost” may refer to a feature positioned closer to the top of a page than another feature. These terms, however, should be construed broadly to include semiconductor devices having other orientations, such as inverted or inclined orientations where top/bottom, over/under, above/below, up/down, and left/right may be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the present disclosure have been described herein for purposes of illustration, but that various modifications may be made without deviating from the scope of the present disclosure. Rather, in the foregoing description, numerous specific details are discussed to provide a thorough and enabling description for embodiments of the present disclosure. One skilled in the relevant art, however, will recognize that the disclosure may be practiced without one or more of the specific details. In other instances, well-known structures or operations often associated with memory systems and devices are not shown, or are not described in detail, to avoid obscuring other aspects of the present disclosure. In general, it should be understood that various other devices, systems, and methods in addition to those specific embodiments disclosed herein may be within the scope of the present disclosure.

What is claimed is:

1. A semiconductor device assembly comprising:
a substrate having a top side and a bottom side opposite the top side;
a contact pad formed at the top side of the substrate;
an under bump metallization (UBM) structure disposed laterally offset from the contact pad;
a redistribution layer electrically coupling the contact pad and the UBM structure;
a copper ball electrically coupled to the UBM structure by a solder material; and
a molding compound disposed over the redistribution structure and at least partially surrounding the copper ball.

2. The semiconductor device assembly of claim 1, wherein the solder material completely encapsulates the copper ball and at least an upper surface of the UBM structure.

3. The semiconductor device assembly of claim 1, wherein a thickness of the molding compound is greater than or equal to a radius of the copper ball.

4. The semiconductor device assembly of claim 1, further comprising an anti-oxidation layer that encapsulates the copper ball and is formed between the solder material and the copper ball.

5. The semiconductor device assembly of claim 1, wherein the UBM structure is formed above the redistribution layer.

6. The semiconductor device assembly of claim 1, wherein the UBM structure does not vertically overlap the contact pad.

7. The semiconductor device assembly of claim 1, wherein the molding compound is in direct contact with at least a portion of the copper ball.

8. A semiconductor device assembly comprising:
a substrate having a top side and a bottom side opposite the top side;
a contact pad formed at the top side of the substrate;
an under bump metallization (UBM) structure disposed laterally offset from the contact pad;
a redistribution layer electrically coupling the contact pad and the UBM structure;
a copper interconnect structure having a substantially hemispherical lower portion electrically coupled to the UBM structure by a solder material; and
a molding compound disposed over the redistribution structure and at least partially surrounding the copper interconnect structure.

9. The semiconductor device assembly of claim 8, wherein the solder material surround the substantially hemispherical lower portion of the copper interconnect structure and at least an upper surface of the UBM structure.

10. The semiconductor device assembly of claim 8, wherein the molding compound has an upper surface coplanar with a planar upper surface of the copper interconnect structure.

11. The semiconductor device assembly of claim 8, wherein the copper interconnect structure has a substantially hemispherical upper portion protruding above an upper surface of the molding compound.

12. The semiconductor device assembly of claim 8, further comprising an anti-oxidation layer that encapsulates the substantially hemispherical lower portion of the copper interconnect structure and that is formed between the solder material and the copper interconnect structure.

13. The semiconductor device assembly of claim 8, wherein the UBM structure is formed above the redistribution layer.

14. The semiconductor device assembly of claim 8, wherein the UBM structure does not vertically overlap the contact pad.

15. The semiconductor device assembly of claim 8, wherein the molding compound is in direct contact with at least a portion of the copper ball.

16. A method of forming a semiconductor device assembly, comprising:
providing a substrate having a top side and a bottom side opposite the top side;
forming a contact pad at the top side of the substrate;
forming a redistribution structure electrically coupled to the contact pad;
forming an under bump metallization (UBM) structure disposed laterally offset from the contact pad and electrically coupled to the redistribution structure;
physically and electrically coupling a copper ball to the UBM structure with a solder material; and
disposing a molding compound over the redistribution structure and at least partially surrounding the copper ball.

17. The method of claim 16, wherein the solder material completely encapsulates the copper ball and at least an upper surface of the UBM structure.

18. The method of claim 16, wherein the copper ball includes an upper portion protruding above an upper surface of the molding compound.

19. The method of claim 16, further comprising planarizing the copper ball to form a substantially hemispherical copper structure with an upper surface coplanar with an upper surface of the molding compound.

20. The method of claim 19, further comprising electrically and physically coupling a solder ball to the upper surface of the substantially hemispherical copper structure.
